(19) United States
(12) Patent Application Publication
(10) Pub. No.: US 2024/0412942 A1
(43) Pub. Date: Dec. 12, 2024

(54) APPARATUS FOR PREPARING ELECTRON MICROSCOPY SAMPLES AND METHODS OF USE THEREOF

(71) Applicant: The Regents of the University of California, Oakland, CA (US)

(72) Inventors: Maxim Armstrong, Granville, OH (US); Robert M. Glaeser, Berkeley, CA (US); Daniel A. Fletcher, Berkeley, CA (US); Bong-Gyoon Han, Castro Valley, CA (US)

(21) Appl. No.: 18/697,079

(22) PCT Filed: Sep. 28, 2022
(86) PCT No.: PCT/US2022/045035

§ 371 Date: Mar. 29, 2024

Related U.S. Application Data
(60) Provisional application No. 63/252,294, filed on Oct. 5, 2021.

(51) Int. Cl. H01J 37/20

(52) U.S. Cl. CPC H01J 37/20; H01J 2237/2002

(57) ABSTRACT

This disclosure provides systems, methods, and apparatus related to electron microscopy sample preparation. In one aspect, a method includes providing an electron microscopy grid. An aqueous suspension including an electron microscopy sample is deposited on the electron microscopy grid. An edge of the electron microscopy grid is contacted with an absorbent material. A thickness of the aqueous suspension is allowed to decrease over a period of time. The aqueous suspension is then frozen.

### RELATED APPLICATIONS

This application claims priority to U.S. Provisional Patent Application No. 63/252,294, filed Oct. 5, 2021, which is hereby incorporated by reference.

### STATEMENT OF GOVERNMENT SUPPORT

This invention was made with government support under Contract No. DE-AC02-05CH11231 awarded by the U.S. Department of Energy and under Grant No. 1R21GM135666-01 awarded by the National Institutes of Health. The government has certain rights in this invention.

### TECHNICAL FIELD

This disclosure relates generally to apparatus and methods for preparing electron microscopy samples and more specifically to apparatus and methods for preparing electron microscopy grids of vitrified biological samples.

### BACKGROUND

For transmission electron cryo-microscopy of hydrated biomolecules, a thin sample of vitreous ice containing the molecules, cell organelles, or whole cells of interest is created. Most cryo-electron microcopy (cryo-EM) samples are prepared using some variation of the traditional technique. In the traditional technique, a droplet of an aqueous suspension containing the molecule or other biological material is deposited on a carbon film of an electron microscopy grid by a micropipette. Excess liquid is removed by blotting the electron microscopy grid with a piece of absorbent material (e.g., filter paper) before the grid is immersed in liquid ethane.

Originally, this technique was performed manually, often in a room cooled to the dew point to prevent evaporation. Some modern commercial instruments automate timing, blot pressure, temperature, and humidity during this process, and are widely used in cryo-EM facilities.

The technique and the instruments currently used to perform this technique, however, produce an inconsistent thickness and distribution of ice. This leads to users preparing multiple samples and searching for areas on the sample grids having sufficient contrast. Because vitreous ice absorbs and scatters electrons, the best contrast is achieved when the ice is only slightly thicker than the sample (e.g., biomolecules) of interest.

### SUMMARY

Described herein are apparatus and methods in which an absorbent material does not contact an aqueous suspension in the same area of an electron microscopy grid that is to be imaged. Instead, the apparatus thins the aqueous suspension over the electron microscopy grid by draining excess liquid to the perimeter of the grid, which may be assisted by one or more of the following: (1) a flow of air (e.g., humid air) to push aqueous suspension away from the imaging area; (2) an acceleration of the electron microscopy grid; or (3) a temperature gradient or surfactant gradient across the aqueous suspension disposed on the electron microscopy grid to create a gradient in surface tension and subsequent flow. The resulting thin aqueous suspension is then immersed in a cryogenic liquid for vitrification of the aqueous suspension. The apparatus and methods remove the tortuous boundary conditions that occur when an absorbent material is pressed onto the entire area of an electron microscopy grid, which is not reproducible. Further, the apparatus and methods do not preclude the use of affinity electron microscopy grids, which bind molecules to the substrate in a structure-friendly way, and which thereby prevent diffusion of the molecules to, and denaturation of the molecules at, the air-water interface. As a result, the apparatus and methods have the potential to improve repeatability, control, and throughput of sample preparation for cryo-EM.

One innovative aspect of the subject matter described in this disclosure can be implemented in a method including providing an electron microscopy grid, depositing an aqueous suspension including an electron microscopy sample on the electron microscopy grid, contacting an edge of the electron microscopy grid with an absorbent material, allowing a thickness of the aqueous suspension to decrease over a period of time, and freezing the aqueous suspension.

In some implementations, the edge of the electron microscopy grid does not include a region of the electron microscopy grid that is to be imaged in an electron microscope when the edge of the electron microscopy grid is contacted with the absorbent material.

In some implementations, the thickness of the aqueous suspension decreases over a period of time via physical processes that do not require evaporation to occur.

In some implementations, the method further includes directing a stream of air to a portion of a surface of the electron microscopy grid prior to or while allowing the thickness of the aqueous suspension to decrease over a period of time. In some implementations, the portion of the surface of the electron microscopy grid to which the stream of air is directed is proximate a top of the electron microscopy grid, and the absorbent material is in contact with the edge of the electron microscopy grid proximate a bottom of the electron microscopy grid. In some implementations, the portion of the surface of the electron microscopy grid to which the stream of air is directed is proximate a center of the electron microscopy grid, and the edge of the electron microscopy grid with which the absorbent material is in contact includes an outer diameter of the electron microscopy grid.

In some implementations, the air of the stream of air is humid air. In some implementations, a relative humidity of the humid air is about 50% to 100%.

In some implementations, freezing the aqueous suspension is performed by immersing the electron microscopy grid with the aqueous suspension disposed thereon in a cryogenic liquid. In some implementations, the cryogenic liquid comprises liquid ethane.

In some implementations, a volume of aqueous suspension deposited on the electron microscopy grid is about 3 microliters or less.

In some implementations, the absorbent material comprises filter paper.

In some implementations, freezing the aqueous suspension is performed when the thickness of the aqueous suspension on the electron microscopy grid is about 20 nanometers to 200 nanometers.

In some implementations, the depositing, the contacting, and the allowing are performed at a first temperature and a first relative humidity. In some implementations, the first temperature is about 20° C. to 25° C. and the first relative humidity is about 50% to 100%.

In some implementations, the aqueous suspension includes a surfactant. In some implementations, the contacting and the allowing are performed in an atmosphere that includes a surfactant.

Another innovative aspect of the subject matter described in this disclosure can be implemented in an apparatus including a chamber, a grid holder, an absorbent material holder, and a reservoir. The chamber is operable to be maintained at a first temperature and a first relative humidity. The grid holder is operable to hold an electron microcopy grid. The absorbent material holder is operable to hold an absorbent material such that the absorbent material is in contact with an edge of the electron microscopy grid. The reservoir is operable to contain a cryogenic liquid. The reservoir is positioned such that the electron microscopy grid can be immersed in the cryogenic liquid contained in the reservoir (e.g., the grid holder holding the electron microcopy grid are immersed in the cryogenic liquid).

In some implementations, the apparatus further includes a reflection interference contrast microscope. An objective lens of the reflection interference contrast microscope is positioned to image a surface of the electron microscopy grid.

In some implementations, the apparatus further includes a sample deposition device. The sample deposition device is operable to deposit an aqueous suspension including an electron microscopy sample on a surface of the electron microscopy grid. In some implementations, the sample deposition device include a pipette.

In some implementations, the apparatus further includes a nozzle. The nozzle is positioned to direct a stream of air at a surface of the electron microscopy grid. In some implementations, the air of the stream of air is humid air. In some implementations, a relative humidity of the humid air is about 50% to 100%.

In some implementations, the cryogenic liquid comprises liquid ethane.

In some implementations, the first temperature is about 20° C. to 25° C. and the first relative humidity is about 50% to 100%.

In some implementations, the absorbent material comprises filter paper.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a flow diagram illustrating a method of preparing an electron microscopy sample.

FIG. 2 shows an example of a schematic illustration of an electron microscopy grid.

FIG. 3 shows an example of a schematic illustration of an apparatus for preparing an electron microscopy sample.

FIG. 4 shows an example of a schematic illustration of an electron microscopy grid in an apparatus for preparing an electron microscopy sample.

FIG. 5 shows an example of a schematic illustration of an electron microscopy grid in an apparatus for preparing an electron microscopy sample.

FIGS. 6A and 6B show examples of schematic illustrations of an absorbent material used in the embodiments described herein.

FIG. 7 shows an example of a schematic illustration of an absorbent material used in the embodiments described herein.

FIGS. 8A-8C, 9A-9C, 10A-10C, and 11A-11C show schematic illustrations of different methods of thinning an aqueous suspension according to methods described herein.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

The terms “about” or “approximate” and the like are synonymous and are used to indicate that the value modified by the term has an understood range associated with it, where the range can be ±20%, ±15%, ±10%, ±5%, or ±1%. The terms “substantially” and the like are used to indicate that a value is close to a targeted value, where close can mean, for example, the value is within 80% of the targeted value, within 85% of the targeted value, within 90% of the targeted value, within 95% of the targeted value, or within 99% of the targeted value.

The apparatus and methods described herein eliminate direct contact between an electron microscopy grid and an absorbent material (e.g., filter paper) over the portion of the electron microscopy grid to be imaged. This aids in eliminating or eliminates the tortuous boundaries that result in uneven and unrepeatable ice thickness. Instead of using only capillary action to assist in the removal of suspension from the imaging area, suspension may also be removed using a flow of air (e.g., humid air), an acceleration of the electron microscopy grid, or a temperature gradient across the aqueous suspension disposed on the electron microscopy grid.

In these methods, some absorbent material is still present, close to the edge or about at the edge of the grid, to act as a sink for excess suspension, but such absorbent material does not come into contact with the center of the grid where the ice is imaged. Embodiments of the apparatus and methods would be generally useful in the preparation of aqueous samples for vitrification, especially for imaging using single-particle cryo-EM or electron cryo-tomography (cryo-ET). Embodiments of the apparatus and methods may also be useful for removing excess aqueous suspension around isolated subcellular organelles (e.g., mitochondria, chloroplasts, mitotic spindles, cilia and flagella, clathrin coated vesicles), whole cells, or a monolayer of cells on the substrate before vitrification when preparing cryo-electron tomography samples.

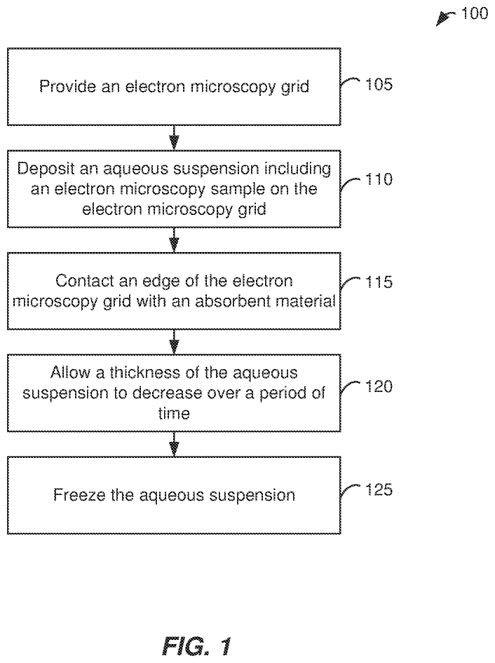

FIG. 1 shows an example of a flow diagram illustrating a method of preparing an electron microscopy sample. Starting at block 105 of a method 100 shown in FIG. 1, an electron microscopy grid is provided. An electron microscopy grid is a grid upon which a sample can be placed. The grid can be placed in an electron microscopy specimen stage that can be inserted into the electron microscope. Electron microscopy grids are generally used in transmission electron microscopy (TEM).

An electron microscopy grid can be made of a number of materials or a combination or alloy of such materials. In some embodiments, the electron microscopy grid comprises gold, molybdenum, titanium, or copper. It is believed that molybdenum has a thermal expansion that is matched with carbon, which may desirable in some cases. In some embodiments, an electron microscopy grid is an about 3 millimeter (mm) diameter disk (e.g., 3.05 mm diameter) that has a thickness and mesh size ranging from about 3 microns to 100 microns. In some embodiments, an electron microscopy grid has a thickness of about 30 microns and a mesh size of about 100 microns.

In some embodiments, the electron microscopy grid comprises a first surface and a second surface, and the first surface of the electron microscopy grid has a carbon film disposed thereon. In some embodiments, the carbon film is hydrophilic. In some embodiments, a carbon film can be made to be hydrophilic by exposure to a glow discharge. In some embodiments, the carbon film has a thickness of about 10 nanometers (nm) to 25 nm, or about 12 nm. In some embodiments, the carbon film is a chemically derivatized thin carbon. In some embodiments, the carbon film is a continuous carbon film. In some embodiments, the carbon film is a holey carbon film. A holey carbon film differs from a continuous carbon film in that a holey carbon film has holes defined in the carbon film. In some embodiments, the holes in the holey carbon film have a specific size. In some embodiments, the holes in the holey carbon film have a cross-sectional dimension of about 1 micron, about 2 microns, or about 1 micron to 2 microns. For example, when the holes in the holey carbon film are circular, the holes may have a diameter of about 1 micron, about 2 microns, or about 1 micron to 2 microns.

In some embodiments, the electron microscopy grid is an affinity grid. An electron microscopy grid that is able to immobilize biological macromolecules in a structure-friendly way is referred to herein as being an “affinity grid.” There are many different types of affinity grids, including electron microcopy grids including a glow-discharge treated carbon film, a functionalized carbon film, graphene oxide, functionalized graphene or graphene oxide, monolayers of charged lipids or ligand-functionalized lipids, and a monolayer including streptavidin crystals.

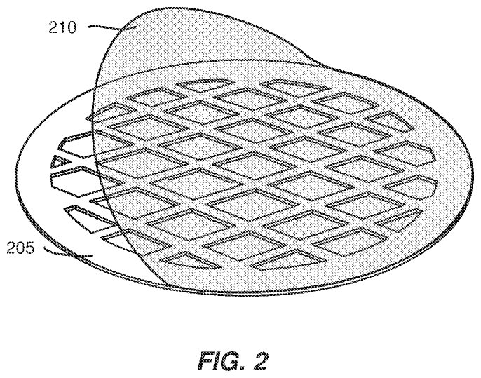

FIG. 2 shows an example of a schematic illustration of an electron microscopy grid. The electron microcopy grid 200 shown in FIG. 2 can be used in the method 100. The electron microscopy grid 200 comprises a disk of metal defining a mesh 205 and a carbon film 210 disposed on a first side of the disk of metal.

Turning back to FIG. 1, at block 110 an aqueous suspension including an electron microscopy sample is deposited on the electron microscopy grid. In some embodiments, a volume of aqueous suspension deposited on the electron microscopy grid is about 3 microliters or less.

At block 115, an edge of the electron microscopy grid is contacted with an absorbent material. In some embodiments, the absorbent material comprises filter paper.

In some embodiments, the edge of the electron microscopy grid does not include a region of the electron microscopy grid that is to be imaged in an electron microscope. For example, in some embodiments, the absorbent material is contacted to a portion of the flat ring of the about 3 mm diameter electron microscopy grid that is not part of the mesh defined by the electron microscopy grid. In some embodiments, the absorbent material is contacted to the flat ring of the about 3 mm diameter electron microscopy grid (i.e., the cylindrical cross-section of the electron microscopy grid) that is not part of the mesh defined by the electron microscopy grid. In some embodiments, the absorbent material is contacted to the about 30 micron thickness of the electron microscopy grid.

In some embodiments, when the operation at blocks 115 and 120 are performed, the electron microscopy grid is in a substantially vertical orientation. “Substantially vertical orientation” is meant to indicate that a line perpendicular to the circular surface of an electron microscopy grid would be substantially parallel to the surface of the ground. In some embodiments, when the operation at blocks 115 and 120 are performed, the electron microscopy grid is in a substantially horizontal orientation. “Substantially horizontal orientation” is meant to indicate that the circular surface of an electron microscopy grid would be substantially parallel to the surface of the ground.

At block 120, a thickness of the aqueous suspension is allowed to decrease over a period of time. In some embodiments, at block 120 water of the aqueous suspension is removed from the electron microscopy grid. In some embodiments, some of the electron microscopy sample or samples in the aqueous suspension may be removed when the thickness of the aqueous suspension is allowed to decrease over a period of time. In some embodiments, the thickness of the aqueous suspension decreases via physical processes that do not require evaporation to occur. When the thickness of the aqueous suspension is decreasing, a “liquid bridge” is maintained between the aqueous suspension disposed on the electron microscopy grid and the aqueous suspension that is being drawn into the absorbent material. The risk of breaking this “liquid bridge” prior to the thickness of the aqueous suspension decreasing to a specific thickness is greater if the absorbent material is in contact with the about 30 micron thickness of the electron microscopy grid compared to a portion of the flat ring or the flat ring of the electron microscopy grid.

At block 125, the aqueous suspension is frozen. That is, the aqueous suspension is frozen while it is disposed on the electron microscopy grid. In some embodiments, the aqueous suspension is frozen by immersing the electron microscopy grid with the aqueous suspension disposed thereon in a cryogenic liquid. For example, the electron microscopy grid may be immersed in a cryogenic liquid contained in a reservoir (e.g., a thermally-insulated reservoir). In some embodiments, the aqueous suspension is frozen by spraying a cryogenic liquid on the electron microscopy grid. In some embodiments, the cryogenic liquid comprises liquid ethane. In some embodiments, the aqueous suspension is frozen when the thickness of the aqueous suspension on the electron microscopy grid is about 20 nm to 200 nm, or about 100 nm.

In some embodiments, the operations in blocks 110, 115, and/or 120 are performed in a controlled atmosphere. For example, the controlled atmosphere may be at a first temperature and a first relative humidity. A controlled atmosphere can prevent unwanted evaporation of the aqueous suspension from the electron microscopy grid. In some embodiments, the first temperature is about 4° C. to 37° C., or about 20° C. to 25° C. (e.g., room temperature). In some embodiments, the first relative humidity is about 50% to 100%. In some embodiments, the first relative humidity is below 100% relative humidity so that evaporation helps to thin the aqueous suspension. A controlled atmosphere might also be used to help to ensure that various gasses (e.g., oxygen or carbon dioxide) that meet the conditions under which living cells (that are soon to be vitrified) can live.

In some embodiments, before or during block 120, a stream of air is directed to a portion of a surface of the electron microscopy grid. In some embodiments, the air of the stream of air is humid air. For example, in some embodiments, a relative humidity of the humid air is about 50% to 100%, or about 95% to 100%. Humid air helps to prevent evaporation of the aqueous suspension. In some embodiments, the stream of air is laminar (i.e., not turbulent).

In some embodiments, the portion of the surface at which the stream of air is directed is proximate the edge of the electron microscopy grid and flowing across the surface of the electron microscopy grid. For example, the stream of air may be directed proximate the top of the electron microscopy grid when the electron microscopy grid is positioned in the substantially vertical orientation. An absorbent material is in contact with an edge of the electron microscopy grid opposite (e.g., across the about 3 mm diameter grid) the edge at which the air is directed. For example, the absorbent material may be in contact with the grid proximate the bottom of the electron microscopy grid when the electron microscopy grid is positioned in the substantially vertical orientation. The stream of air stream creates a gradient in stagnation pressure and entrains aqueous suspension flow via shear stress, driving the bulk of the aqueous suspension into the absorbent material.

In some embodiments, the stream of air is directed at an oblique angle (i.e., not perpendicular or parallel to a circular surface of the electron microscopy grid) to the portion of the surface of the electron microscopy grid. In some embodiments, when the electron microscopy grid is in a substantially vertical orientation, the stream of air flows from the top of the circular surface of an electron microscopy grid to the bottom of the circular surface of the electron microscopy grid.

In some embodiments, the portion of the surface of the electron microscopy grid to which the stream of air is directed is proximate a center of the electron microscopy grid. In some embodiments, the portion of the surface of the electron microscopy grid to which the stream of air is directed is proximate a center of the electron microscopy grid and the stream of air is substantially perpendicular to the surface of the electron microscopy grid. The edge of the electron microscopy grid with which the absorbent material is in contact includes the flat ring of the electron microscopy grid.

In some embodiments, to help prevent the aqueous suspension from dewetting from the electron microscopy grid, the surface of the electron microscopy grid on which the aqueous suspension is hydrophilic. Dewetting is when a thin film of liquid ruptures on a substrate, which may lead to the formation of a droplet on the substrate. Another consequence of dewetting may be that the electron microscopy grid retains none of the aqueous suspension (i.e., the electron microscopy grid becomes completely dry). In some embodiments, to help prevent the aqueous suspension from dewetting from the electron microscopy grid, a surfactant is provided at the air-water interface to lower the air-water surface tension. In some embodiments, the surfactant does not denature the electron microscopy sample when the sample comprises biomolecules. For example, in some embodiments, the aqueous suspension includes a surfactant (e.g., liposomes in solution). In some embodiments, the surfactant includes lipids (e.g., lipids in the form of small “bilayer” vesicles that then spread as lipid monolayers at the air-water interface). In some embodiments, the surfactant includes biochemically mild detergents such as, for example, NP40, CHAPS, fluorinated FOS choline, dodecyl maltoside, or octyl glucoside.

In some embodiments, a surfactant (e.g., a volatile surfactant, such as gaseous nonafluorobutyl methyl ether) is added to the ambient, surrounding atmosphere of the liquid containing the sample. This is yet another reason for having a control atmosphere under which operations of the method 100 are performed. For example, in some embodiments, the operations in block 115 and 120 are performed in an atmosphere that includes a surfactant (e.g., a volatile surfactant). In some embodiments, the surfactant is insoluble in water and in biochemical buffers. In some embodiments, a surfactant monolayer adds a disjoining pressure that prevents the thin aqueous suspension film from dewetting the surface of the grid as the film thickness drops below about 100 nanometers.

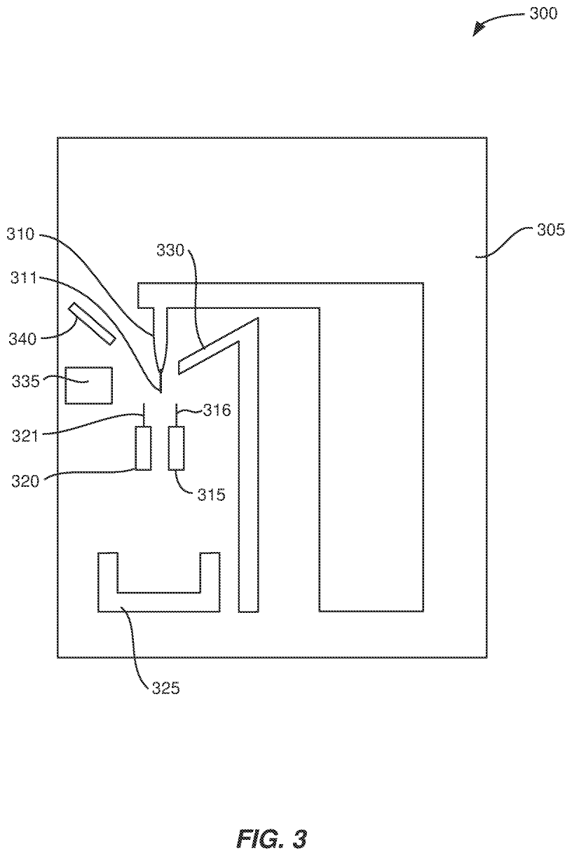

FIG. 3 shows an example of a schematic illustration of an apparatus for preparing an electron microscopy sample. Embodiments of the apparatus 300 shown in FIG. 3 can be used to perform the method 100.

The apparatus 300 shown in FIG. 3 includes a chamber 305, a grid holder 310, a first absorbent material holder 315 and a second absorbent material holder 320, and a reservoir 325. The chamber 305 is operable to be maintained at a first temperature and a first relative humidity. In some embodiments, the first temperature is about 4° C. to 37° C., or about 20° C. to 25° C. In some embodiments, the first relative humidity is about 50% to 100%. In some embodiments, the chamber 305 includes a heater and a humidifier (not shown) to maintain the chamber at a specified first temperature and a specified first relative humidity.

The grid holder 310 is operable to hold an electron microcopy grid 311 in the chamber 305. The grid holder 310 is in contact with an edge of the electron microcopy grid 311. In some embodiments, the grid holder 310 comprises a set of tweezers. In some embodiments, the grid holder 310 is disposed in the chamber 305.

The first absorbent material holder 315 is operable to hold an absorbent material 316 such that the absorbent material is in contact with an edge of the electron microscopy grid 311. The second absorbent material holder 320 is operable to hold an absorbent material 321 such that the absorbent material is in contact with an edge of the electron microscopy grid 311. In some embodiments, when the apparatus 300 is in operation, either first absorbent material holder 315 or the second absorbent material holder 320 holds absorbent material. The absorbent material holder not holding absorbent material can be used to contact the electron microscopy grid 311 to serve as a brace or a stabilizer for the electron microscopy grid 311.

In some embodiments, the first absorbent material holder 315 and/or the second absorbent material holder 320 comprises a set of tweezers. In some embodiments, the absorbent material 316 and/or 312 comprises filter paper. In some embodiments, the first material absorbent material holder 315 and/or the second absorbent material holder are disposed in the chamber 305. In some embodiments, the apparatus 300 includes a single absorbent material holder.

The reservoir 325 is operable to contain a cryogenic liquid. The reservoir is positioned such that the electron microscopy grid 311 can be immersed in the cryogenic liquid contained in the reservoir 325 (e.g., the grid holder 310 holding the electron microcopy grid 311 can be immersed in the cryogenic liquid or plunged into the cryogenic liquid). In some embodiments, the reservoir 325 is a thermally-insulated reservoir. In some embodiments, the cryogenic liquid comprises liquid ethane. In some embodiments, the reservoir 325 is disposed in the chamber 305.

In some embodiments, the apparatus 300 does not include a reservoir 325. Instead, in some embodiments, the apparatus 300 includes a cryogen nozzle (not shown). In some embodiments, the cryogen nozzle is positioned to spray a stream of cryogenic liquid (e.g., a stream of liquid ethane) on the electron microscopy grid 311.

In some embodiments, the apparatus 300 further includes nozzle 330. In some embodiments, the nozzle 330 is positioned to direct a stream of air proximate an edge of the electron microcopy grid 311 across the surface of the electron microscopy grid to the opposite edge of the electron microscopy grid. In some embodiments, the nozzle 330 is positioned to direct a stream of air proximate the top edge of the electron microcopy grid 311 when the grid is in a substantially vertical orientation. In some embodiments, the nozzle is positioned to direct a steam of air proximate a center of the electron microcopy grid 311. In some embodiments, nozzle 330 is disposed in the chamber 305. In some embodiments, the air of the stream of air is humid air. In some embodiments, a relative humidity of the humid air is about 50% to 100%, or about 95% to 100%.

In some embodiments, the apparatus 300 further includes a reflection interference contrast microscope 335 (e.g., a 550 nm reflection interference contrast microscope). An objective lens of the reflection interference contrast microscope 335 is positioned to image a surface of the electron microscopy grid 311. In some embodiments, the components of a reflection interference contrast microscope 330, except for an objective lens, are disposed outside of the chamber 305.

In some embodiments, the apparatus 300 further includes a sample deposition device 340. The sample deposition device 340 is operable to deposit an aqueous suspension including an electron microscopy sample on a surface of the electron microscopy grid 311. In some embodiments, the sample deposition device includes a pipette.

In some embodiments, the apparatus 300 includes motors, servos, and controllers. For example, in some embodiments, a controller is used to adjust and maintain a specified first temperature and a specified first relative humidity of the chamber 305. The controller may be connected to the heater and the humidifier and adjust the temperature and the relative humidity of the chamber 305 based on a temperature sensor and a humidity sensor in the chamber. Similarly, in some embodiments, a second controller is used to the adjust and maintain the humidity of the air of the stream of air from the nozzle 330.

In some embodiments, a motor is used to adjust the position of the electron microscopy grid 311 relative to the absorbent material 316 held in the first absorbent material holder 315. In some embodiments, a second motor is used to adjust the position of the absorbent material 316 held in the absorbent material holder 315 relative to the electron microscopy grid 311. Such motors allow for the position of the electron microscopy grid 311 and the absorbent material 316 to be adjusted when the apparatus 300 is in operation. In some embodiments, a motor is used to adjust the position of the absorbent material 321 held in the absorbent material holder 320 relative to the electron microscopy grid 311.

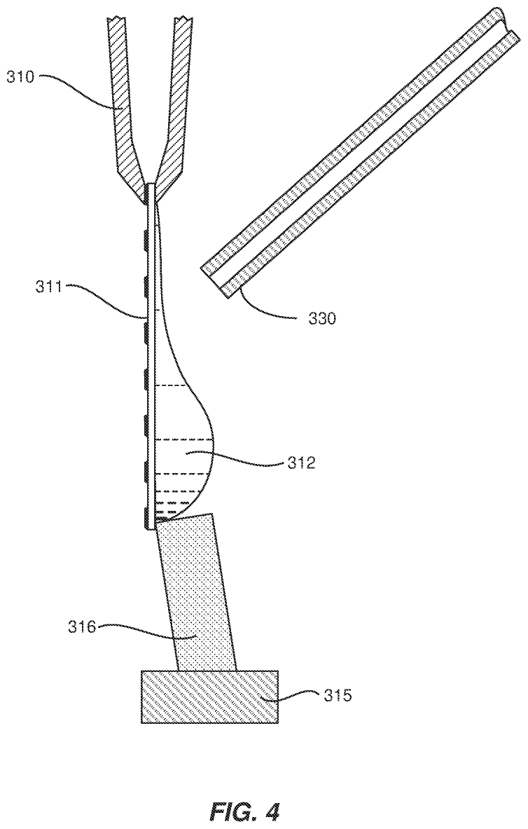

FIG. 4 shows an example of a schematic illustration of an electron microscopy grid in an apparatus for preparing an electron microscopy sample. FIG. 4 is an enlarged view of a portion of the apparatus 300 shown in FIG. 3.

As shown in FIG. 4, the grid holder 310 is holding the electron microscopy grid 311. The first absorbent material holder 315 is holding absorbent material 316. The absorbent material 316 is in contact with an edge (i.e., a bottom edge) of the electron microscopy grid 311. Aqueous suspension 312 deposited on the electron microscopy grid 311 is flowing into the absorbent material 316, which decreases a thickness of the aqueous suspension 312. The nozzle 330 is blowing air proximate an edge (i.e., a top edge) of the electron microscopy grid 311 and across the surface of the electron microscopy grid on which the aqueous suspension 312 is disposed.

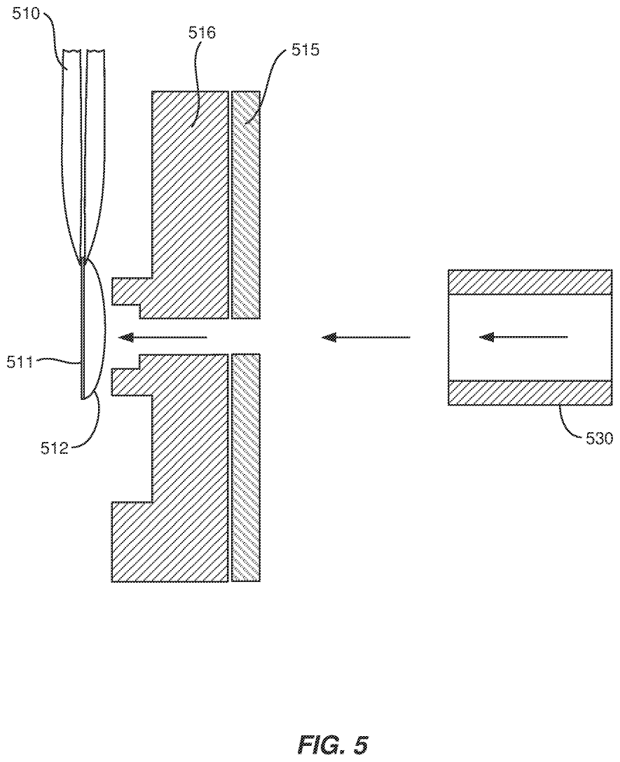

FIG. 5 shows an example of a schematic illustration of an electron microscopy grid in an apparatus for preparing an electron microscopy sample. As shown in FIG. 5, a grid holder 510 is holding the electron microscopy grid 511. An absorbent material holder 515 is holding absorbent material 516. The absorbent material 516 is in contact with the ring of the electron microscopy grid 511 (i.e., the cylindrical cross-section of the electron microscopy grid). Aqueous suspension 512 deposited on the electron microscopy grid 511 is flowing into the absorbent material 516, which decreases a thickness of the aqueous suspension 512. A nozzle 530 is blowing air proximate a center of the electron microscopy grid, with the flow of air being substantial perpendicular to the surface of the electron microscopy grid 511.

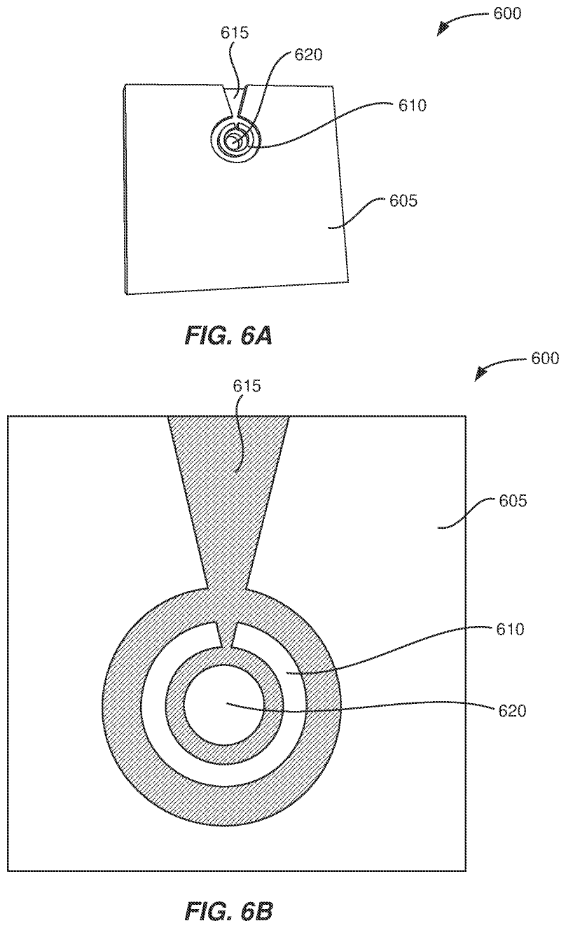

FIGS. 6A and 6B show examples of schematic illustrations of an absorbent material used in the embodiments described herein. For example, the absorbent material shown in FIGS. 6A and 6B can be used in the portion of the apparatus shown in FIG. 5.

As shown in FIGS. 6A and 6B, an absorbent material 600 comprises a block of absorbent material 605 with features defined in a surface of the block. In some embodiments, the block of absorbent material 605 is about 0.1 mm to 4 mm thick, about 2 mm to 4 mm thick, or about 0.1 mm to 0.3 mm thick. Defined in the surface of the block of absorbent material 605 are a cylinder 610 and a cutout 615 (e.g., a V-shaped trench) that allows for the electron microscopy grid to be contacted with the cylinder 610 when the electron microscopy grid is held by a grid holder. In some embodiments, an inner diameter of the cylinder 610 is about 1.5 mm to 2 mm in diameter. In some embodiments, an outer diameter of the cylinder 610 is about 3 mm to 3.5 mm. In some embodiments, the block of absorbent material 605 defines a through hole 620. The through hole 620 allows for the flow of air to the surface of an electron microscopy grid. In some embodiments, the through hole 620 is about 1.5 mm to 2 mm in diameter.

In some embodiments, the block of absorbent material 605 can be fabricated by stacking pieces of filter paper (e.g., about 15 pieces) on top of one another, bonding them with an adhesive (e.g., a spray adhesive). In some embodiments, the block of absorbent material 605 includes a single piece of filter paper. In some embodiments, a laser machining tool can be used form the features on the surface of the block of absorbent material 605, including the through hole 620.

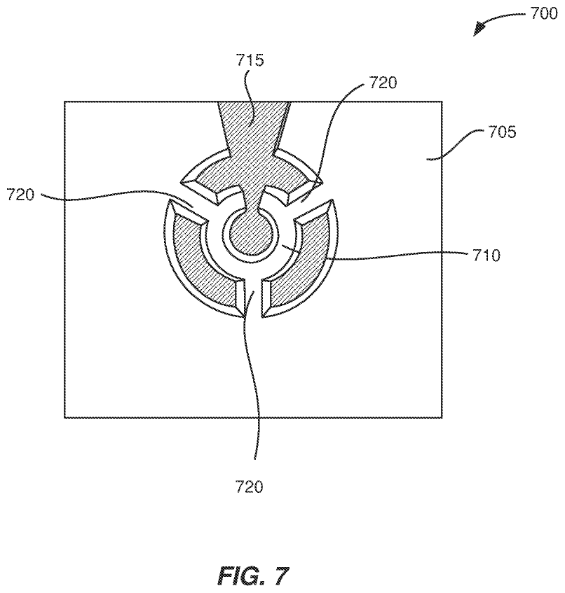

FIG. 7 shows an example of a schematic illustration of an absorbent material used in the embodiments described herein. For example, the absorbent material shown in FIG. 7 can also be in the portion of the apparatus shown in FIG. 5.

As shown in FIG. 7, an absorbent material 700 comprises a block of absorbent material 705 with features defined in a surface of the block. In some embodiments, the block of absorbent material 605 comprises about 1 to 3 pieces of filter paper, or 1 piece of filter paper, bonded to a block of plastic (e.g., lucite). Defined in the surface of the block of absorbent material 705 are a cylinder 710 and a cutout 715 (e.g., a V-shaped trench) that allows for the electron microscopy grid to be contacted with the cylinder 710 when the electron microscopy grid is held by a grid holder. In some embodiments, an inner diameter of the cylinder 710 is about 1.5 mm to 2 mm in diameter. In some embodiments, an outer diameter of the cylinder 710 is about 3 mm to 3.5 mm. In some embodiments, spokes 720 connect the absorbent material making up the cylinder to the bulk of absorbent material.

The number, length, and width of the spokes can be changed to increase or decrease a rate at which aqueous suspension is removed from the electron microscopy grid to the absorbent material. The capacity of cylinder 710 for aqueous suspension is generally filled up upon contact with an electron microscopy grid. To remove more of the aqueous suspension from the electron microscopy grid, the cylinder 710 may be connected to the effectively “infinite bulk” of dry absorbent material lying beyond the trench that surrounds the cylinder 710 with the spokes 720. If the spokes 720 that form this connection are both thin and long, the flow resistance that they impose (i.e., a high flow resistance) can slow the completion of the draining process of the aqueous suspension from the electron microscopy grid. If the spokes 720 that form this connection are both thick and short, the flow resistance that they impose (i.e., a low flow resistance) can speed up the completion of the draining process of the aqueous suspension from the electron microscopy grid.

In some embodiments, the block of absorbent material 705 defines a through hole (not shown) at a center of the cylinder 710. The through hole allows for the flow of air to the surface of an electron microscopy grid. In some embodiments, the through hole is about 1.5 mm to 2 mm in diameter.

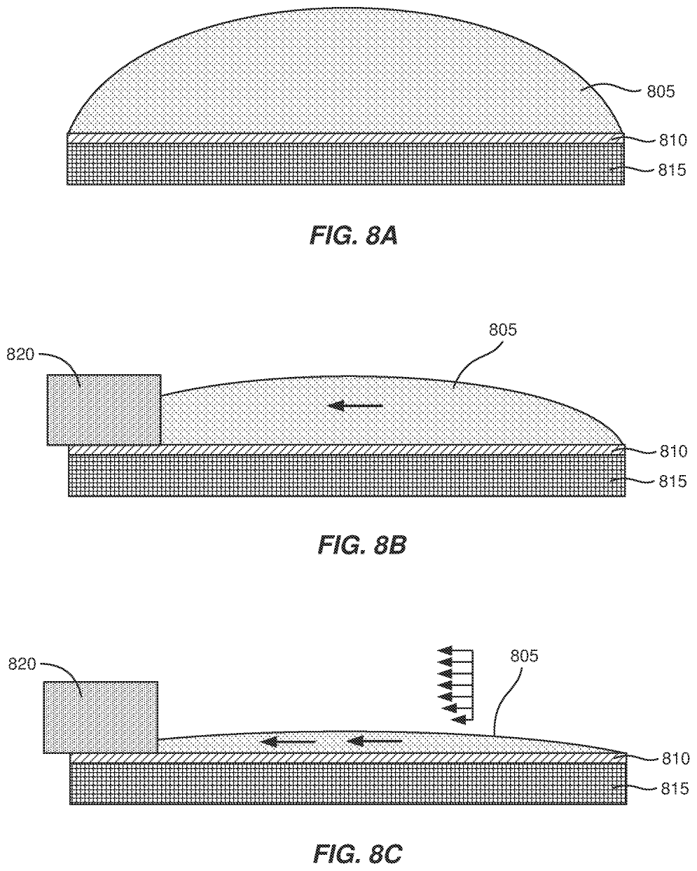

FIGS. 8A-8C, 9A-9C, 10A-10C, and 11A-11C show schematic illustrations of different methods of thinning an aqueous suspension according to methods described herein. FIGS. 8A-8C show schematic illustrations of a method of thinning an aqueous suspension using air (e.g., humid air). The method shown in FIGS. 8A-8C is similar to embodiments described with respect to FIG. 4. FIG. 8A shows a droplet of an aqueous suspension 805 deposited on the carbon film 810 disposed on the disk of metal defining a mesh 815 comprising the electron microscopy grid. FIG. 8B shows an absorbent material 820 placed at an edge of the electron microscopy grid to serve as a sink for excess aqueous suspension 805. Some amount of the aqueous suspension is drawn into the absorbent material 820 via capillary action. FIG. 8C shows that when air is blown across the aqueous suspension 805 towards the absorbent material 820, the absorbent material 820 pulls the aqueous suspension 805, further thinning the aqueous suspension 805. After this, the air stream and absorbent material 820 are removed and the aqueous suspension 805 disposed on the electron microscopy grid is frozen by immersing the electron microscopy grid in a cryogen (e.g., liquid ethane) or using a stream of cryogenic liquid (e.g., a stream of liquid ethane).

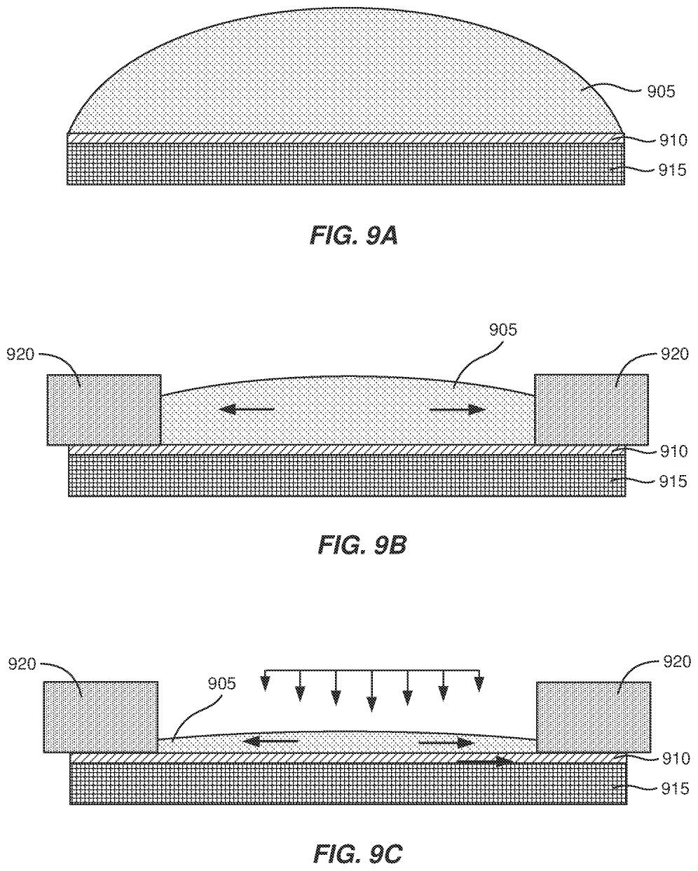

FIGS. 9A-9C show schematic illustrations a method of thinning an aqueous suspension using air (e.g., humid air). The method shown in FIGS. 9A-9C is similar to embodiments described with respect to FIG. 5. FIG. 9A shows a droplet of an aqueous suspension 905 deposited on the carbon film 910 disposed on the disk of metal defining a mesh 915 comprising the electron microscopy grid. FIG. 9B shows an absorbent material 920 placed around the circumference of the electron microscopy grid to serve as a sink for excess aqueous suspension 905. FIG. 9C shows air being blown orthogonally towards the aqueous suspension 905, driving the aqueous suspension 905 towards the periphery of the electron microscopy grid both through drag and a gradient in stagnation pressure from the air flow.

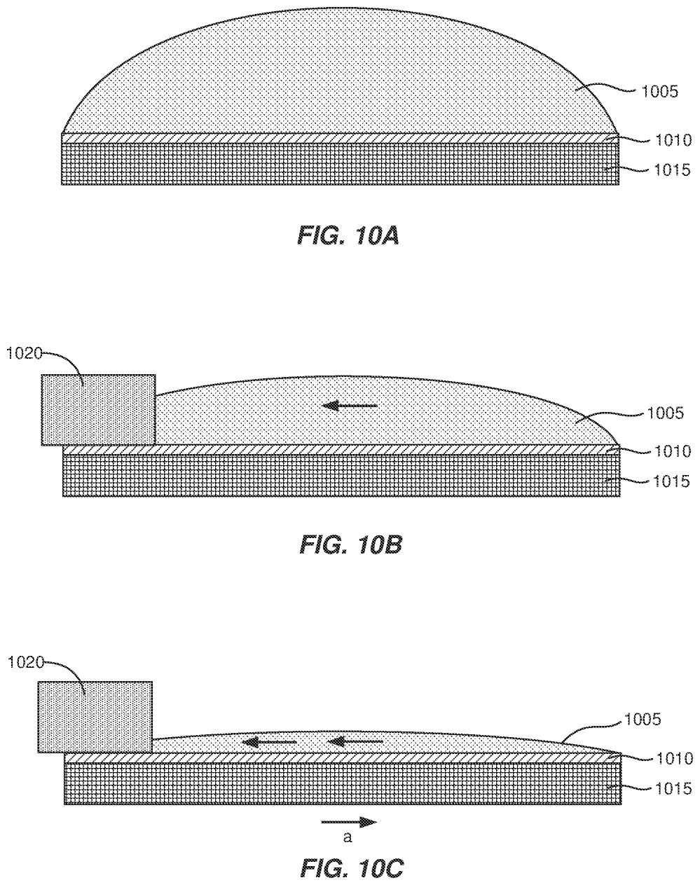

FIGS. 10A-10C show schematic illustrations of a method of thinning an aqueous suspension using acceleration. FIG. 10A shows a droplet of an aqueous suspension 1005 deposited on the carbon film 1010 disposed on the disk of metal defining a mesh 1015 comprising the electron microscopy grid. FIG. 10B shows an absorbent material 1020 placed at an edge of the electron microscopy grid to serve as a sink for excess aqueous suspension 1005. FIG. 10C shows that when the electron microscopy grid is accelerated away from the absorbent material 1020 (e.g., by attaching the electron microscopy grid to the end of a rotary arm), aqueous suspension 1005 is accelerated towards the absorbent material 1020.

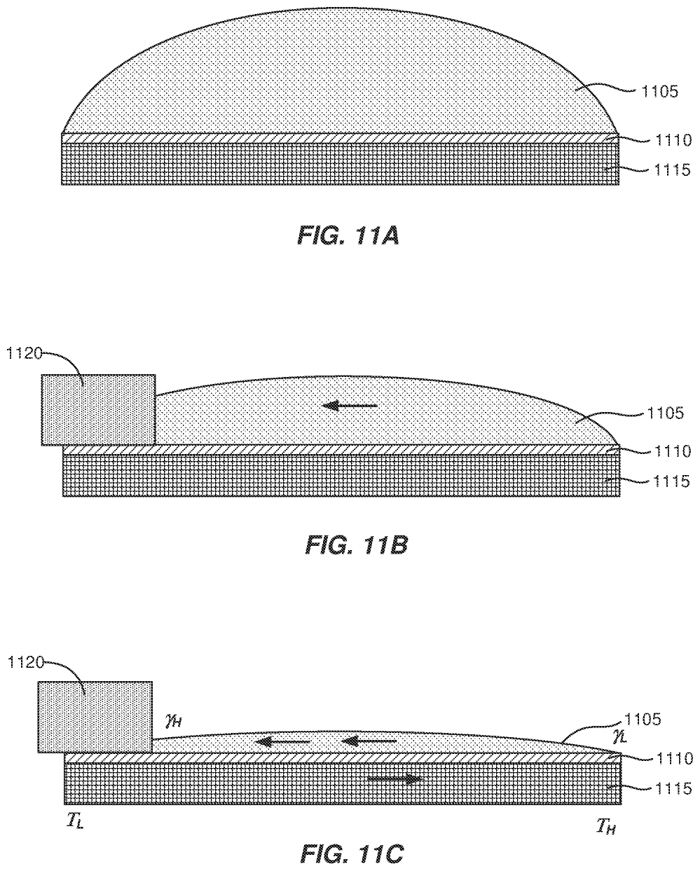

FIGS. 11A-11C show schematic illustrations of a method of thinning an aqueous suspension using a temperature gradient. FIG. 11A shows a droplet of an aqueous suspension 1105 deposited on the carbon film 1110 disposed on the disk of metal defining a mesh 1115 comprising the electron microscopy grid. FIG. 11B shows an absorbent material 1120 placed at an edge of the electron microscopy grid to serve as a sink for excess aqueous suspension 1105. FIG. 11C shows that a gradient in temperature (T_{H} to T_{L}) maintained across the electron microscopy grid, with the lower temperature (T_{L}) being proximate the absorbent material 1120, creates a gradient in surface tension of the aqueous suspension 1105 that drives the flow of the aqueous suspension 1105 towards the absorbent material 1120. The gradient in temperature is insufficient to denature the electron microscopy sample in the aqueous suspension 1105, but is sufficient to create a gradient in surface tension in the aqueous suspension 1105

### CONCLUSION

Further details regarding some of the implementations described herein can be found in Han B-G, Armstrong M, Fletcher D A and Glaeser R M (2022) “Perspective: Biochemical and Physical Constraints Associated with Preparing Thin Specimens for Single-Particle Cryo-EM.” Front. Mol. Biosci. 9:864829, which is hereby incorporated by reference.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

1. A method comprising:
(a) providing an electron microscopy grid;
(b) depositing an aqueous suspension including an electron microscopy sample on the electron microscopy grid;
(c) contacting an edge of the electron microscopy grid with an absorbent material;
(d) allowing a thickness of the aqueous suspension to decrease over a period of time; and
(e) freezing the aqueous suspension.

2. The method of claim 1, wherein in operation (c), the edge of the electron microscopy grid does not include a region of the electron microscopy grid that is to be imaged in an electron microscope.

3. The method of claim 1, wherein operation (d) occurs via physical processes that do not require evaporation to occur.

4. The method of claim 1, further comprising:
prior to or during operation (d), directing a stream of air to a portion of a surface of the electron microscopy grid.

5. The method of claim 4, wherein the portion of the surface of the electron microscopy grid to which the stream of air is directed is proximate a top of the electron microscopy grid, and wherein the absorbent material is in contact with the edge of the electron microscopy grid proximate a bottom of the electron microscopy grid.

6. The method of claim 4, wherein the portion of the surface of the electron microscopy grid to which the stream of air is directed is proximate a center of the electron microscopy grid, and wherein the edge of the electron microscopy grid with which the absorbent material is in contact includes an outer diameter of the electron microscopy grid.

7. The method of claim 4, wherein the air of the stream of air is humid air.

8. (canceled)

9. The method of claim 1, wherein operation (e) is performed by immersing the electron microscopy grid with the aqueous suspension disposed thereon in a cryogenic liquid.

10. (canceled)

11. The method of claim 1, wherein a volume of the aqueous suspension deposited on the electron microscopy grid in operation (b) is about 3 microliters or less.

12. The method of claim 1, wherein the absorbent material comprises filter paper.

13. The method of claim 1, wherein operation (e) is performed when the thickness of the aqueous suspension on the electron microscopy grid is about 20 nanometers to 200 nanometers.

14. The method of claim 1, wherein operations (b), (c), and (d) are performed at a first temperature and a first relative humidity.

15. (canceled)

16. The method of claim 1, wherein the aqueous suspension includes a surfactant.

17. The method of claim 1, wherein operations (c) and (d) are performed in an atmosphere that includes a surfactant.

18. An apparatus comprising:
a chamber, the chamber operable to be maintained at a first temperature and a first relative humidity;
a grid holder, the grid holder operable to hold an electron microcopy grid;
an absorbent material holder, the absorbent material holder operable to hold an absorbent material such that the absorbent material is in contact with an edge of the electron microscopy grid; and
a reservoir, the reservoir operable to contain a cryogenic liquid, the reservoir being positioned such that the electron microscopy grid can be immersed in the cryogenic liquid contained by the reservoir.

19. (canceled)

20. The apparatus of claim 18, further comprising:
a sample deposition device, wherein the sample deposition device is operable to deposit an aqueous suspension including an electron microscopy sample on a surface of the electron microscopy grid.

21. (canceled)

22. The apparatus of claim 18, further comprising:
a nozzle, wherein the nozzle is positioned to direct a stream of air at a surface of the electron microscopy grid.

23. The apparatus of claim 18, wherein the air of the stream of air is humid air.

24. The apparatus of claim 18, wherein a relative humidity of the humid air is about 50% to 100%.

25. (canceled)

26. The apparatus of claim 18, wherein the first temperature is about 20° C. to 25° C., and wherein the first relative humidity is about 50% to 100%.

27. (canceled)
